(19) United States
(12) Patent Application Publication
(10) Pub. No.: US 2025/0212704 A1
(43) Pub. Date: Jun. 26, 2025

(54) FERROELECTRIC STORAGE DEVICE AND METHOD FOR MANUFACTURING SUCH A DEVICE

(71) Applicant: COMMISSARIAT A L'ENERGIE ATOMIQUE ET AUX ENERGIES ALTERNATIVES, PARIS (FR)

(72) Inventors: Julien BORREL, GRENOBLE CEDEX 09 (FR); Justine BARBOT, GRENOBLE CEDEX 09 (FR); Jean COIGNUS, GRENOBLE CEDEX 09 (FR); Laurent GRENOUILLET, GRENOBLE CEDEX 09 (FR); Rachid HIDA, GRENOBLE CEDEX 09 (FR); Eric JALAGUIER, GRENOBLE CEDEX 09 (FR)

(21) Appl. No.: 18/990,667

(22) Filed: Dec. 20, 2024

(30) Foreign Application Priority Data
Dec. 21, 2023 (FR) 2314898

(51) Int. Cl. H10N 70/00; H10B 63/00; H10N 70/20

(52) U.S. Cl. CPC H10N 70/066; H10B 63/00; H10N 70/026; H10N 70/043; H10N 70/25; H10N 70/8265; H10N 70/8836

(57) ABSTRACT

A method for manufacturing a ferroelectric storage device includes depositing a first layer, depositing, by a physical vapour deposition method, a layer of ferroelectric material, the layer of ferroelectric material including a first part having a first thickness and a second part having a second thickness, the first thickness and the second thickness being distinct, and depositing a second layer, the layer of ferroelectric material extending between the first layer and the second layer.

### CROSS-REFERENCE TO RELATED APPLICATIONS

This application claims priority to French Patent Application No. 2314898, filed Dec. 21, 2023, the entire content of which is incorporated herein by reference in its entirety.

### FIELD

The present invention generally relates to the field of microelectronics. It relates more particularly to the field of non-volatile memories.

In particular, the invention relates to a ferroelectric storage device. It also relates to a method for manufacturing such a ferroelectric storage device.

### BACKGROUND

The main quality of FeRAM (Ferroelectric Random Access Memory)-type ferroelectric memories is that they are non-volatile, i.e. they retain the information stored even when the voltage is turned off. They also have the advantage of consuming little energy and having low write and read times relative to other types of non-volatile memory such as FLASH memory.

Ferroelectric memories of the FeRAM type generally take the form of a stack in which a layer of ferroelectric material is positioned between two metal electrodes. Ferroelectric memories are capacitive type memories with two remanent polarisation states, +Pr and −Pr. The operation of these ferroelectric memories is based on the ferroelectric properties of the ferroelectric material placed between two metal electrodes.

More particularly, as regards the operation of FeRAM type ferroelectric memories, by the application of a potential difference between the two electrodes creating an electric field having a value greater than a positive coercive field +Ec, the ferroelectric memory is placed in a high remanent polarisation state +Pr and by the application of a potential difference creating an electric field having a value less than the negative coercive field −Ec, the ferroelectric memory is placed in a low remanent polarisation state −Pr.

The high remanent polarisation state +Pr then corresponds to the binary logic state ‘0’ and the low remanent polarisation state −Pr to the binary logic state ‘1’, which allows information to be stored.

Furthermore, when the application of the potential difference between the two metal electrodes is stopped, the remanent polarisation state remains: this explains the non-volatile nature of ferroelectric memories.

For reading, it is assumed that the memory is in a given state and a voltage is applied. This voltage is for example positive, greater than the voltage creating an electric field with a value greater than the positive coercive field +Ec. Thus, if the memory was already in the high remanent polarisation state +Pr, this polarisation state is unchanged and no current spike is observed (or a very small current spike may be observed). Conversely, if the memory was in the low remanent polarisation state −Pr, a much larger current peak is observed.

The consequence of this read operation is that it destroys the polarisation state.

Ferroelectric Tunnel Junction (FTJ) memories are also known. FTJ-type ferroelectric memories generally take the form of a stack in which a layer of ferroelectric material is positioned between two metal electrodes. FTJ ferroelectric memories are resistive type memories with two opposite polarisation states for the layer of ferroelectric material. The operation of these ferroelectric memories is based on ferroelectric properties of the ferroelectric material placed between two metal electrodes.

More particularly, as regards the operation of FTJ-type ferroelectric memories, the two polarisation states respectively correspond to two different resistance levels: a high-resistance level, corresponding for example to a high polarisation state +Pr, and a low-resistance level, corresponding to a low polarisation state −Pr. By way of example, the low-resistance level has an electrical resistance approximately one thousand times lower than that of the high-resistance level.

In the case of FTJ-type ferroelectric memories, the read operation comprises the application of a read voltage −Vr. The read voltage −Vr is, for example, negative and lower in absolute value than a voltage Vc associated with the coercive field. This enables non-destructive reading to be carried out by measuring a tunnel current.

In order to increase memory density, it is known to implement a so-called “multi-level” storage. This “multi-level” storage is associated with different polarisation states, on which it will be possible to store information.

Document “Multilevel data storage memory using deterministic polarization control.” by Lee, Daesu et al. in Advanced materials, vol. 24(3), 2012, 402-406, doi:10.1002/adma.201103679 describes a FeRAM-type ferroelectric memory with several storage levels. In this example, as is represented in FIG. 1 (representing the course of the polarisation P as a function of the applied voltage V), the memory can be placed in several intermediate remanent polarisation states Pr₁, Pr₂, Pr₃, Pr₄, Pr₅, Pr₆, Pr₇ (Pro corresponding to the state 0 of low polarisation). It will therefore be possible to store information at different levels. Thanks to this “multi-level” storage, it is possible to code several states per memory (herein, in the example, eight states are coded), whereas in a standard cell only two states are accessible (states 0 or 1 only). Thus, the information contained in a memory with “multi-level” storage is equivalent to that contained in several standard memories.

In practice, in this example, to implement this storage on the different intermediate levels, each intermediate polarisation state Pr₁, Pr₂, Pr₃, Pr₄, Pr₅, Pr₆, Pr₇ is associated with a corresponding current. Thus, upon application of a voltage between the electrodes, an associated ferroelectric current is read. This current then makes it possible to identify the intermediate polarisation state Pr₁, Pr₂, Pr₃, Pr₄, Pr₅, Pr₆, Pr₇ concerned and therefore to deduce the information initially stored in this intermediate polarisation state Pr₁, Pr₂, Pr₃, Pr₄, Pr₅, Pr₆, Pr₇ of the ferroelectric memory.

However, some drawbacks are observed in such high-density memories. For example, it can be difficult to distinguish between two intermediate polarisation states that are close to each other. Indeed, an overlap between the different intermediate polarisation states may be encountered. In such a case, the application of a voltage (between the electrodes) to this overlap zone does not allow the associated current, and therefore the intermediate remanent polarisation state associated therewith, to be deduced with some certainty.

### SUMMARY

The present invention therefore aims to improve high-density ferroelectric storage devices by allowing unambiguous distinction between different polarisation states.

An aspect of the invention then relates to a method for manufacturing a ferroelectric storage device comprising the steps of:
providing a support layer,
forming a cavity in the support layer, the cavity comprising a bottom wall and a side wall, the side wall forming a tilt angle relative to a direction normal to the bottom wall,
depositing a first layer into the cavity,
depositing, by a physical vapour deposition method, a layer of ferroelectric material into the cavity, the layer of ferroelectric material comprising a first part having a first thickness and a second part having a second thickness, the first thickness and the second thickness being distinct, depositing the layer of ferroelectric material comprising steps of: a) depositing the first portion of the layer of ferroelectric material along a first direction associated with a first deposition angle formed relative to a direction normal to the bottom wall, b) depositing the second part of the layer of ferroelectric material along a second direction associated with a second deposition angle formed relative to the direction normal to the bottom wall, the second deposition angle and the first deposition angle being different, and then
depositing a second layer into the cavity, the layer of ferroelectric material extending between the first layer and the second layer.

Thus, according to the manufacturing method in accordance with an aspect of the invention, the layer of ferroelectric material in the ferroelectric storage device according to an aspect of the invention has a non-uniform thickness. This variability in thickness leads to non-uniformity in the ferroelectric properties of the ferroelectric storage device. This non-uniformity of properties especially makes it possible to increase differences between the voltage ranges to be applied to store information in the different intermediate polarisation states.

Indeed, the different thicknesses mean that, for a given (write) voltage, the electric field is greater in regions of lower thickness. In other words, to write information in an intermediate polarisation state associated with a low thickness, a higher voltage has to be applied. The differences in thickness therefore lead to differences in the voltages to be applied to encode information in the different intermediate polarisation states.

The different thicknesses used are therefore associated with different intermediate polarisation states in the ferroelectric storage device.

In other words, by virtue of the non-uniformity created in the layer of ferroelectric material (due to thickness variability), differences between the intermediate polarisation states are created.

Further to the characteristics just discussed in the preceding paragraphs, the method for manufacturing ferroelectric storage device according to one aspect of the invention may have one or more additional characteristics from among the following, considered individually or in according to any technically possible combinations:
depositing the layer of ferroelectric material is anisotropically implemented;
depositing the layer of ferroelectric material is non-conformally implemented;
depositing the layer of ferroelectric material is implemented by an ion beam deposition method or by an evaporation deposition method;
the first deposition angle and the second deposition angle are less than 90 degrees;
depositing the first part of the layer of ferroelectric material is implemented by orienting a first unidirectional ion beam along the first direction and depositing the second part of the layer of ferroelectric material is implemented by orienting a second unidirectional ion beam along the second direction;
a change in the orientation of the first unidirectional ion beam and/or of the second unidirectional ion beam is performed by tilting the support layer;
a change in the orientation of the first unidirectional ion beam and/or the second unidirectional ion beam is performed by tilting a target from which the first unidirectional ion beam and/or the second unidirectional ion beam is formed;
the layer of ferroelectric material comprises hafnium dioxide or hafnium dioxide doped with a doping element or an alloy of HfₓZr₁₋ₓO₂, where 0<x<1; and
there is provided, before the step of depositing the second layer, a step of implanting a doping element into the layer of ferroelectric material so as to dope the layer of ferroelectric material with the doping element.

### BRIEF DESCRIPTION OF THE FIGURES

Further characteristics and benefits of the invention will become clearer from the description thereof given below, by way of indicating and in no way limiting purposes, with reference to the appended figures, wherein:

FIG. 1 illustrates the different intermediate polarisation states in the case of a FeRAM-type ferroelectric memory with several storage levels,

FIG. 2 schematically represents an example of a ferroelectric storage device in accordance with the invention,

FIG. 3 schematically illustrates the principle of depositing a layer of ferroelectric material in the ferroelectric storage device in accordance with an embodiment of the invention,

FIG. 4 represents, in the form of a flow chart, a first example of a method for manufacturing the ferroelectric storage device in accordance with the invention,

FIG. 5 illustrates step E102 of the manufacturing method represented in FIG. 4,

FIG. 6 illustrates step E104 of the manufacturing method represented in FIG. 4,

FIG. 7 illustrates step E106a of the manufacturing method represented in FIG. 4,

FIG. 8 illustrates step E106b of the manufacturing method represented in FIG. 4,

FIG. 9 illustrates step E106c of the manufacturing method represented in FIG. 4,

FIG. 10 illustrates step E108 of the manufacturing method represented in FIG. 4,

FIG. 11 represents, in the form of a flow chart, a second example of a method for manufacturing the ferroelectric storage device in accordance with the invention,

FIG. 12 illustrates step E206b of the manufacturing method represented in FIG. 11,

FIG. 13 illustrates step E206c of the manufacturing method represented in FIG. 11, and

FIG. 14 illustrates step E208 of the manufacturing method represented in FIG. 11.

For greater clarity, identical or similar elements are identified by identical reference signs throughout the figures.

### DETAILED DESCRIPTION

The present invention aims to improve the manufacture of ferroelectric storage devices. In particular, the present invention relates to a high-density storage device wherein several polarisation states are used to store information. The present invention then aims to improve the definition of the polarisation states so as to be able to clearly distinguish between them in order to then be able to read the stored piece of information associated with each of the polarisation states.

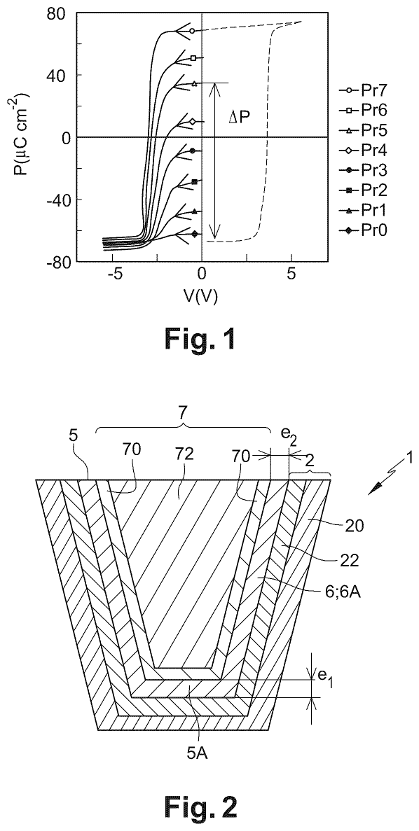

FIG. 2 represents a ferroelectric storage device 1 (also noted device 1 in the following) in accordance with an embodiment of the invention. As is visible in this figure, the ferroelectric storage device 1 comprises a first layer 2, a second layer 7 and a layer of ferroelectric material 5 which is disposed between the first layer 2 and the second layer 7.

The ferroelectric storage device 1 is in the form of a stack of layers. The first layer 2, the layer of ferroelectric material 5 and the second layer 7 form the different layers of this stack.

As will be described in more detail later, along with the manufacturing method associated, the ferroelectric storage device 1 is formed in a cavity 50 (visible in FIGS. 5 to 10 and FIGS. 12 to 14).

This cavity 50 is for example formed in a support layer 10. In other words, the cavity 50 forms a part of the support layer 10 which has an overall “U”-shaped profile (as will be seen later, the side limbs of the “U”-shape can herein be tilted relative to the base of the “U”-shape). Herein, the different layers of the ferroelectric storage device 1 have a similar shape profile to the part 50 with a “U”-shaped profile of the support layer 10.

This support layer 10 is herein formed of a dielectric material. For example, the support layer 10 comprises silicon oxide SiO₂.

The support layer may comprise a plurality of sub-layers. For example, the support layer may comprise another layer of dielectric material formed beneath the layer comprising silicon oxide SiO₂. This other layer comprises, for example, silicon nitride SiN or silicon carbonitride SiCN.

The cavity 50 comprises a bottom wall 52 and a side wall 55. The bottom wall 52 corresponds to the base of the “U” shape and the side wall 55 corresponds to the side limbs of the “U” shape. The side wall 55 forms a tilt angle β relative to an axis z, corresponding to a direction normal to the bottom wall 52. In an embodiment, this tilt angle β is non-zero. This tilt angle β is less than 50 degrees, for example. In an embodiment, it is less than 35 degrees, for example. Alternatively, this tilt angle may be zero (the side wall is therefore vertical).

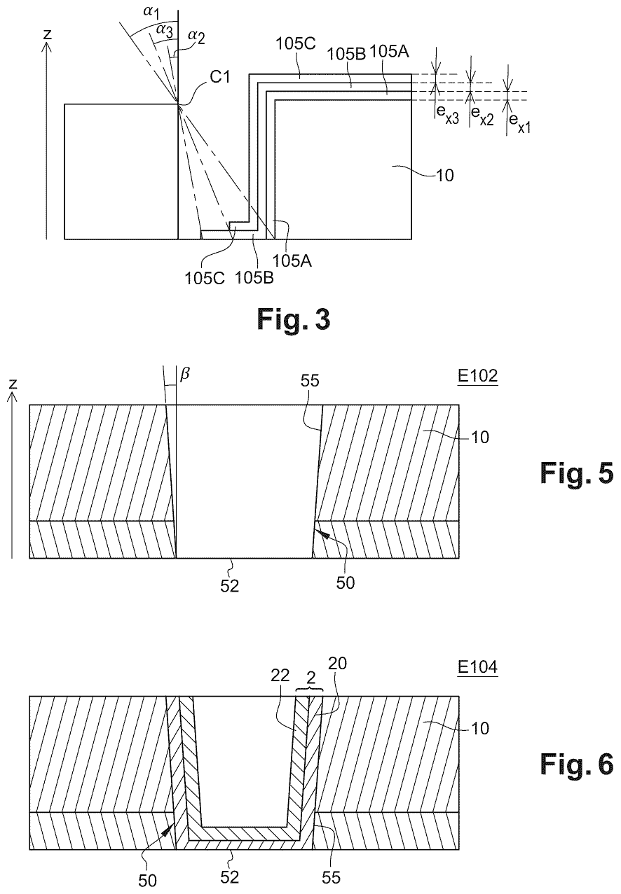

In FIG. 3, the tilt angle of the side wall 55 is substantially zero, whereas in FIGS. 5 to 10 and FIGS. 12 to 14, this tilt angle β is non-zero.

One or more aspects of the present invention finds an application within the scope of ferroelectric storage devices formed in such a support provided with a cavity having a bottom wall and a side wall.

The stack forming the ferroelectric storage device 1 extends from the bottom wall 52 and the side wall 55. This stack then comprises several parts: one extending from the bottom wall 52 and another extending from the side wall 55. For the part formed on the bottom wall 52, the different layers of the stack extend in parallel to each other. The same applies to the part extending from the side wall 55 (the different layers of the stack also extend in parallel to each other on this side wall 55).

Alternatively, the side wall of the cavity can comprise a plurality of portions forming distinct angles relative to a direction normal to the bottom wall. In other words, the side wall of the cavity could have a plurality of breaks of slope.

Each of the layers forming the ferroelectric storage device 1 is now described.

The first layer 2 is made of an inert conductive material. This first layer 2 comprises, for example, a metal material.

According to a first example (not represented), the first layer comprises a single layer. The conductive material of this single layer comprises, for example, titanium nitride TiN. Alternatively, the conductive material may be tantalum nitride TaN or tungsten W. Still alternatively, other conductive materials may be used (and in particular metal nitride more generally).

As is visible in the example represented in FIG. 2, the first layer 2 is in the form of a two-layer structure. It comprises herein a first sub-layer 20 and a second sub-layer 22.

The second sub-layer 22 is disposed on the first sub-layer 20.

The first sub-layer 20 comprises a metal conductive material. In an embodiment, it comprises titanium Ti or tantalum nitride TaN.

The first sub-layer 20 has a thickness of between 3 and 20 nanometres (nm). In an embodiment, this thickness is between 5 and 10 nm.

This first sub-layer 20 acts both as a protective layer and as a contact layer for electrically connecting the device 1 to its electronic control and read circuit.

The second sub-layer 22 is disposed on the first sub-layer 20. It is in direct contact with the layer of ferroelectric material 5. In other words, the second sub-layer 22 extends between the first sub-layer 20 and the layer of ferroelectric material 5.

The second sub-layer 22 is formed of a conductive material comprising a transition metal. This conductive material is, for example, titanium nitride TiN. Alternatively, it may be other conductive materials such as tantalum nitride TaN or tungsten W.

For example, when the second sub-layer 22 comprises titanium nitride, the first sub-layer 20 is formed of a conductive material such as titanium Ti.

Alternatively, when the second sub-layer 22 comprises tantalum, the first sub-layer 20 is formed, for example, of tantalum nitride TaN.

Still alternatively, when the second sub-layer 22 comprises tungsten, the first sub-layer 20 is formed of a conductive material of titanium Ti.

Herein, the thickness of the second sub-layer 22 is between 10 and 100 nm. In an embodiment, this thickness is between 5 and 10 nm.

Alternatively, the first layer may comprise a semiconductor material. This semiconductor material comprises silicon, for example.

The layer of ferroelectric material 5 is disposed on the first layer 2. Alternatively, the layer of ferroelectric material can be deposited onto another layer previously present on the first layer.

This layer of ferroelectric material 5 comprises an active material having variable resistance. This layer of ferroelectric material 5 is based, for example, on hafnium dioxide HfO₂. In the present description, by the term “based on”, it is meant that the layer concerned comprises more than 50% of the element mentioned after this term (for example herein, this means that the layer of ferroelectric material 5 comprises more than 50% hafnium dioxide).

Alternatively, hafnium dioxide can be doped with a doping element. In the present description, the expression “doping” of a layer relates to the introduction into the material of the layer concerned of atoms of another material referred to as a “doping element”.

Herein, in an embodiment, the used doping element is silicon Si. In the case of silicon, the layer of ferroelectric material based on hafnium dioxide is for example exposed to a dose of dopant of between 1.10¹⁴ cm⁻² and 1.10¹⁵ cm⁻² in order to obtain a presence of between 0.7 and 7% of silicon atoms in the layer of ferroelectric material. In an embodiment, the dose of dopant is between 0.3.10¹⁵ cm⁻² and 1.10¹⁵ cm⁻².

Alternatively, other doping elements can be used, such as aluminium Al, germanium Ge, gadolinium Gd, yttrium Y, lanthanum La, scandium Sc or nitrogen N.

Still alternatively, the layer of ferroelectric material may comprise an alloy of the form HfₓZr₁₋ₓO₂, where 0<x<1. For example, it is possible to use a ternary HfZrO₂ alloy (for example Hf_{0.5}Zr_{0.5}O₂) as the ferroelectric material. Still alternatively, the layer of ferroelectric material can be made of aluminium scandium nitride (AlScN).

As is visible in FIGS. 2, 8 and 12, the layer of ferroelectric material 5 comprises at least a first part 5A and a second part 6; 6A.

In the examples visible in FIGS. 2 and 8, the first part 5A extends at the bottom wall 52 of the cavity 50, while the second part 6 extends at the side wall 55 of the cavity 50.

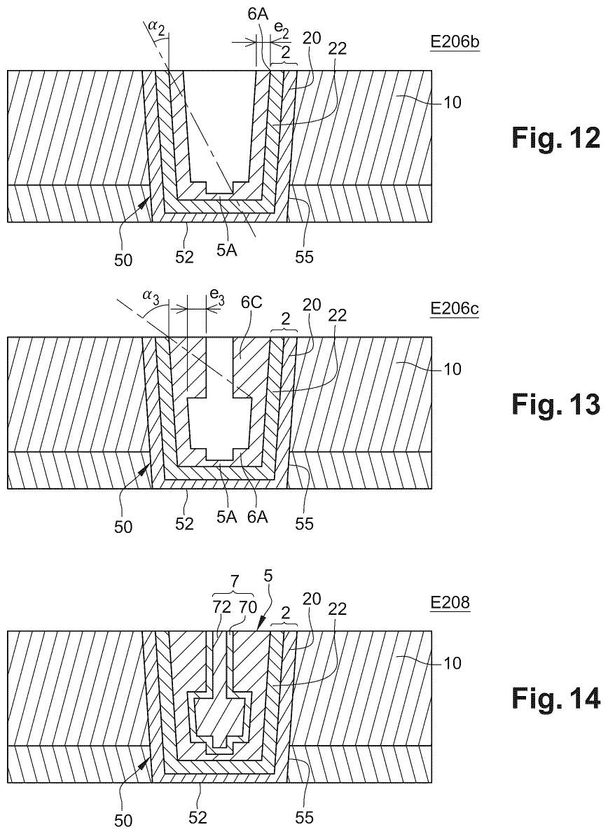

In the example represented in FIG. 12, the first part 5A extends at the bottom wall 52 of the cavity 50 and the second part 6A extends at the side wall 55 of the cavity 50 as well as partly at the bottom wall 52 (herein on the first part 5A).

Beneficially, according to an embodiment of the invention, the first part 5A

has a first thickness e₁ and the second part 6; 6A has a second thickness e₂. In the present invention, the thickness of a part of a layer is defined as the distance separating the two faces of the part of the layer concerned. In other words, the thickness corresponds to the characteristic dimension of the layer concerned in a direction parallel to a direction normal to the faces of the part of the layer concerned.

Herein, the first thickness e₁ and the second thickness e₂ are distinct. In other words, the layer of ferroelectric material 5 has a non-uniform thickness. In other words, the layer of ferroelectric material 5 has a variable thickness.

Differences in thickness are essential characteristics of the ferroelectric storage device for obtaining different polarisation states.

Thus, by virtue of an embodiment of the invention, the different thicknesses used for the layer of ferroelectric material introduce a non-uniformity in the ferroelectric properties of the layer of ferroelectric material. This non-uniformity of properties especially makes it possible to increase differences between the voltage ranges to be applied to encode the information in the different intermediate polarisation states. This makes it possible to avoid overlapping between the voltage ranges concerned and therefore to unambiguously identify the intermediate polarisation states related to the stored information.

In order to obtain very distinct polarisation states (i.e. with no overlap between the ranges of voltages to be applied to reach them), the ratio of the second thickness e₂ to the first thickness e₁ is, in an embodiment, between 2 and 4.

In practice, the first thickness e₁ is, for example, between 3 and 7 nm. In an embodiment, this first thickness e₁ is in the order of 4 nm.

The second thickness e₂ is, for example, between 8 and 17 nm. In an embodiment, this second thickness e₂ is in the order of 10 nm.

Herein, the second thickness e₂ is therefore greater than the first thickness e₁. This means that a higher voltage will have to be applied to enable the information in the intermediate polarisation state associated with the second thickness e₂ (compared with the first thickness e₁) to be stored.

The thickness ranges considered in an embodiment of the invention make it possible to enhance non-uniformities of the ferroelectric properties of the layer of ferroelectric material, so as to make it possible to store information on different intermediate polarisation states and to encode this information by distinguishing distinctly between these different states.

Furthermore, in a plane orthogonal to the direction for defining the thickness, a surface of the first part 5A is defined at one of the faces of the layer of ferroelectric material 5. It is also possible to define the total surface of the layer of ferroelectric material 5 as the surface of one of the faces of the layer of ferroelectric material 5. In other words, the surface of the first part 5A corresponds to part of the total surface of the layer of ferroelectric material 5.

Beneficially according to an embodiment of the invention, the first part 5A has a surface area of at least 15% of the total surface area of the layer of ferroelectric material 5. In other words, the surface area of the first part 5A represents at least 15% of the total surface area of the layer of ferroelectric material 5.

Thus, beneficially according to an embodiment of the invention, non-uniformities (associated with differences in thickness) in the layer of ferroelectric material are not manufacturing artefacts. The fact that the parts associated with the different thicknesses have large surface areas ensures that the polarisation conditions are quite distinct (and therefore that there is no overlap between the voltage ranges to be applied to achieve the different polarisation conditions).

In the case of the ferroelectric storage device represented in FIGS. 9 and 13, the layer of ferroelectric material 5 comprises a third part 6B; 6C. This third part 6B; 6C has a third thickness e₃, distinct from the first thickness e₁ and the second thickness e₂.

In the examples represented in FIGS. 9 and 13, the third part 6B; 6C extends at the side wall 55 of the cavity 50.

This third thickness adds further non-uniformity to the ferroelectric properties of the layer of ferroelectric material 5.

As shown in FIGS. 2, 10 and 14, the second layer 7 is disposed on the layer of ferroelectric material 5.

This second layer 7 comprises, for example, a conductive material. This is especially a metal material.

According to a first example (not represented), the second layer comprises a single layer. The conductive material of this single layer comprises, for example, titanium nitride TiN. Alternatively, the conductive material may be tantalum nitride TaN or tungsten W. Still alternatively, other conductive materials may be used (and in particular metal nitride more generally).

As is visible in FIGS. 2, 10 and 14, the second layer 7 is herein in the form of a two-layer structure. It comprises a first sub-layer 70 and a second sub-layer 72.

The second sub-layer 72 of the second layer 7 is disposed on the first sub-layer 70 associated therewith.

The second sub-layer 72 is formed of a conductive material comprising a transition metal. This conductive material is, for example, titanium nitride TiN.

Alternatively, it may be other conductive materials such as tantalum nitride TaN or tungsten W.

The second sub-layer 72 has a thickness of between 10 and 200 nm.

This second sub-layer 72 acts both as a protective layer and as a contact layer for electrically connecting the device 1 to its electronic control and read circuit.

The first sub-layer 70 is disposed on the layer of ferroelectric material 5. It is in direct contact with the layer of ferroelectric material 5. In other words, the first sub-layer 70 of the second layer 7 extends between the second sub-layer 72 and the layer of ferroelectric material 5.

The second sub-layer 72 comprises a metal conductive material. In an embodiment, it comprises titanium Ti or tantalum Ta.

For example, when the second sub-layer 72 comprises titanium nitride, the first sub-layer 70 is formed of a conductive material such as titanium Ti.

Alternatively, when the second sub-layer 72 comprises tantalum nitride, the first sub-layer 70 is formed of a conductive material such as tantalum Ta.

Still alternatively, when the second sub-layer 72 comprises tungsten, the first sub-layer 70 is formed of a conductive material selected from titanium Ti or tantalum Ta.

Herein, the thickness of the first sub-layer 70 is between 3 and 20 nm.

In practice, in the case of an OxRAM (Oxide Resistive RAM) type memory, when this two-layer structure is used for the second layer 7, the first sub-layer 70 also has the feature of being a layer which will allow the creation of oxygen vacancies in the layer of ferroelectric material 5 (when this first sub-layer 70 is in contact with the layer of ferroelectric material 5). In this case, the first sub-layer 70 comprises a conductive material selected from titanium Ti or tantalum Ta, and the second sub-layer 72 comprises a titanium nitride TiN or a tantalum nitride TaN (so as to form a protective layer). The creation of these oxygen vacancies then improves performance of the ferroelectric storage device by facilitating oxygen exchanges with the layer of ferroelectric material.

In the case of a memory of the FeRAM type, the second layer 7 comprises, for example, a metal nitride or a metal which does not oxidise (such as tungsten W or ruthenium Ru).

In the case of an FTJ type memory, the structure used is that of a FeRAM type memory with the introduction of a layer comprising a dielectric material between the layer of ferroelectric material 5 and the second layer 7. The dielectric material is, for example, a dielectric oxide such as aluminium oxide Al₂O₃ or silicon dioxide SiO₂.

Alternatively, the second layer may comprise a semiconductor material. This semiconductor material comprises silicon, for example.

Beneficially according to an embodiment of the invention, the ferroelectric storage device comprises a layer of ferroelectric material having variable thickness. This variability in thickness results in non-uniformity in the ferroelectric properties of the ferroelectric storage device. This non-uniformity of properties especially makes it possible to increase differences between the voltage ranges to be applied to encode information in the different intermediate polarisation states.

In other words, by virtue of the non-uniformity created in the layer of ferroelectric material (due to thickness variability), differences between the intermediate polarisation states are created.

Alternatively, the layer of ferroelectric material may comprise more than three distinct thicknesses. This can especially be a continuous variation in thickness.

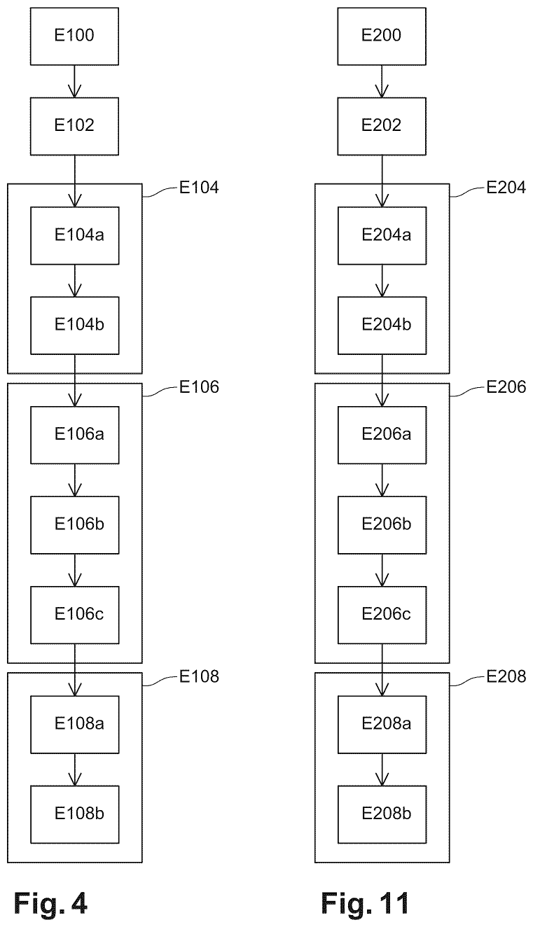

The present invention also relates to a method for manufacturing a ferroelectric storage device 1. FIGS. 4 to 13 relate to this manufacturing method. More particularly, FIGS. 4 to 10 relate to a first example of this method for manufacturing the ferroelectric storage device 1 according to an embodiment of the invention. FIGS. 11 to 14 relate to a second example of the method for manufacturing the ferroelectric storage device 1.

The method for manufacturing ferroelectric storage device 1 finds a favoured application in ferroelectric storage devices formed in a cavity. The specificity of the manufacturing method is to take advantage of the edge of the side wall of the cavity to form different parts of the layer of ferroelectric material with different thicknesses.

FIG. 4 represents, in the form of a flow chart, a first example of the manufacturing method.

As is visible in this FIG. 4, the manufacturing method comprises first of all a step E100 of providing a support layer 10 on which the ferroelectric storage device 1 will be formed. In practice, this support layer 10 is provided with at least one logic component associated with a metal interconnection element (not represented) for connecting the ferroelectric storage device 1 to lower metal levels.

The manufacturing method then continues in step E102, during which the cavity 50 (in which the ferroelectric storage device 1 will be formed) is formed. FIG. 4 illustrates this step E102.

In practice, this step E102 is implemented by anisotropic etching to form the bottom wall 52 and the side wall 55 of the cavity 50. This is for example dry chemical etching.

As described previously, the side wall 55 of the cavity 50 is made in such a way as to form the tilt angle β relative to the axis z parallel to a direction normal to the bottom wall 52. The side wall 55 therefore forms a non-zero tilt angle β relative to an axis z, corresponding to a direction normal to the bottom wall 52.

As is visible in FIG. 4, the manufacturing method continues with step E104 of depositing the first layer 2. FIG. 6 illustrates this step E104.

This first layer 2 is deposited in the cavity 50. More particularly, the first layer 2 is deposited along the bottom wall 52 and the side wall 55 of the cavity 50. The first layer 2 therefore lines and embraces the shape of the cavity 50.

Depositing the first layer 2 is herein conformally made. In this description, by “conformal deposition”, it is meant a deposition implemented in such a way that the layer has a substantially constant thickness at any point. In this description, by “substantially constant”, it is meant a thickness that does not vary by more than 20%, such as by more than 10%, and in an embodiment by more than 5%. For example, the first layer 2 can be formed by an Atomic Layer Deposition (ALD) method.

As previously indicated, the first layer 2 herein comprises a first sub-layer 20 and a second sub-layer 22.

Step E104 of depositing the first layer 2 therefore comprises two sub-steps: a first sub-step E104a of depositing the first sub-layer 20 and a second sub-step E104b of depositing the second sub-layer 22.

The first sub-layer 20 is therefore first deposited, conformally, in the cavity 50 (step E104a). In practice, the first sub-layer 20 is formed, for example, by an atomic layer deposition (or ALD) method or by chemical vapour deposition.

Alternatively, the first sub-layer 20 can be formed by sputtering in a vacuum deposition chamber. In the case where the first sub-layer 20 is formed of titanium nitride, this is a reactive sputtering process.

Then, the second sub-layer 22 of the first layer 2 is conformally deposited onto the first sub-layer 20 (step E104b). The second sub-layer 22 is formed, for example, by sputtering in a vacuum deposition chamber. In practice, the second sub-layer 22 of the first layer 2 is formed in the same deposition chamber as the first sub-layer 20 of the first layer 2.

In the case where the second sub-layer 22 is formed of titanium nitride, this is a reactive sputtering process.

The method then continues with the step E106 of depositing the layer of ferroelectric material 5 onto the first layer 2. More particularly, the first layer of ferroelectric material 5 is deposited onto the second sub-layer 22 of the first layer 2.

Depositing the layer of ferroelectric material 5 is herein anisotropically implemented. Furthermore, depositing the layer of ferroelectric material 5 herein is non-conformal.

In practice, the layer of ferroelectric material 5 is deposited by a Physical Vapour Deposition (PVD) method.

In an embodiment herein, the layer of ferroelectric material 5 is deposited by an Ion Beam deposition (IBD) method. Alternatively, the layer of ferroelectric material can be deposited by a vacuum evaporation deposition method. It is possible to achieve similar deposition rates using a vacuum evaporation deposition method and an ion beam deposition method. In practice, in the case of a vacuum evaporation deposition method, a crucible comprises the material to be deposited. This crucible is heated by the Joule effect. By varying the current intensity, it is then possible to vary the deposition rate.

The anisotropic nature of the deposition is herein based on controlling orientation of a target, from which atoms are extracted, relative to a substrate (herein, for example, the support layer). Atoms extracted from the target then form an ion beam associated with a corresponding direction of deposition. Thus, the anisotropic nature of the deposition is associated with different directions of deposition (using the deposition methods introduced previously).

FIG. 3 schematically illustrates the principle of this anisotropic deposition of the layer of ferroelectric material according to an embodiment of the invention.

In this figure, cavity 50 is represented with a side wall 55 forming an angle of zero relative to the direction normal (parallel to the axis z) to the bottom wall 52. Of course, the principle described hereafter applies in the same way for cavities whose side wall forms a non-zero angle with this direction normal to the bottom wall.

Herein, the different thicknesses of the layer of ferroelectric material are achieved using several depositions by unidirectional ion beam, each along a given direction.

More particularly, in general, the layer of ferroelectric material is obtained by depositing a plurality of portions (at least two) finally forming this layer of ferroelectric material 5. Depositing each of these portions is carried out at an associated deposition angle α₁, α₂, α₃. Each deposition angle α₁, α₂, α₃ is defined relative to a direction normal (parallel to the axis z) to the bottom wall 52 of the cavity 50. Herein, the deposition angles α₁, α₂, α₃ are different from one another. Herein, each deposition angle α₁, α₂, α₃ is, for example, less than 90 degrees. In an embodiment, each deposition angle α₁, α₂, α₃ is between 5 and 85 degrees.

Beneficially according to an embodiment of the invention, the ion beam for conducting deposition of each of these parts is arranged relative to the edge of the side wall 55 of the cavity 50. More particularly herein, each ion beam is arranged relative to a corner C1 formed at the end of the side wall 55 of the cavity 50. More particularly, the ion beam concerned is directed to the support layer and is partly intersected as it crosses the corner C1 formed at the end of the side wall 55 of the cavity 50. The corner C1 then generates a shading effect by intersecting the ion beam, allowing only some zones of the cavity 50 to be exposed to this ion beam.

In other words, the side wall 55 of the cavity 50 produces, for some zones of the cavity, a shading effect, i.e. some zones of the cavity 50 are not reached by the ion beam concerned. In other words, by virtue of the configuration of the ion beams used in an embodiment of the invention, each ion beam (at an associated deposition angle) causes the ferroelectric material to be deposited onto a specific zone of the cavity 50.

In addition, characteristics associated with this ion beam make it possible to adjust thickness of the part of the layer of ferroelectric material 5 deposited. In particular, the thickness of each part of the layer of ferroelectric material 5 deposited herein depends, for example, on the deposition rate and deposition time for forming the ion beam concerned.

Beneficially, use of several deposition angles α₁, α₂, α₃ and adjustment of the parameters of each ion beam then make it possible to make depositions in different zones of the cavity 50 and also to vary thickness of the layer of ferroelectric material 5 in some zones of the cavity 50.

This deposition principle is schematically illustrated in FIG. 3. Depositing a first part 105A of the layer of ferroelectric material 5 is performed at a first deposition angle α₁. As is visible in FIG. 3, according to this deposition, the first part 105A is deposited onto part of the bottom wall 52 and part of the side wall 55 of the cavity 50. This deposition of the first part 105A is implemented at a deposition rate and for a deposition time that makes it possible to obtain a thickness eₓ₁ for this first part 105A.

Elsewhere in the cavity 50, as is visible in FIG. 3, the other zones are not exposed to the ion beam emitted at the first deposition angle α₁, so no layer of ferroelectric material is formed (following this deposition of the first layer 105A) in these zones.

Then, depositing a second part 105B of the layer of ferroelectric material 5 is performed at a second deposition angle α₂. According to FIG. 3, this second part 105B is also deposited onto part of the bottom wall 52 and part of the side wall 55 of the cavity 50. More particularly, as shown in FIG. 3, the second part 105B is partly deposited onto the first layer 105A (which makes it possible to obtain a greater thickness of ferroelectric material for the zones concerned).

This deposition of the second part 105B is implemented at a deposition rate and for a deposition time that makes it possible to obtain a thickness eₓ₂ for this second part 105B. Thus, for the zones of the cavity 50 already provided with the first part 105A, at this stage, the layer of ferroelectric material has a thickness in the order of the sum of the thickness eₓ₁ and the thickness eₓ₂. For the other zones related to the deposition of the second part 105B, the layer of ferroelectric material has the thickness eₓ₂.

Herein too, the zones not exposed to the ion beam emitted at the second deposition angle α₂ are therefore devoid of this second part 105B (and for some zones, which had not been subjected to the ion beam emitted at the first deposition angle α₁, they are, at this stage, completely devoid of ferroelectric material).

As is represented in FIG. 3, depositing a third part 105C of the layer of ferroelectric material 5 is carried out at a third deposition angle α₃. This third part 105C is also deposited onto part of the bottom wall 52 and part of the side wall 55 of the cavity 50. More particularly, as shown in FIG. 3, the third part 105C is partly deposited onto the second layer 105B (which makes it possible to obtain a greater thickness of ferroelectric material for the zones concerned).

This deposition of the third part 105C is implemented at a deposition rate and for a deposition time that makes it possible to obtain a thickness eₓ₃ for this third part 105C. Thus, for the zones of the cavity 50 already provided with the first part 105A and the second part 105B, at this stage, the layer of ferroelectric material has a thickness in the order of the sum of the thickness eₓ₁, the thickness eₓ₂ and the thickness eₓ₃. For the zones of the cavity 50 provided with the second part 105B (only), the layer of ferroelectric material has (at this stage) a thickness in the order of the sum of the thickness eₓ₂ and the thickness eₓ₃. For the other zones related to the deposition of the third part 105C, the layer of ferroelectric material has the thickness eₓ₃.

Herein too, the zones not exposed to the ion beam emitted at the third deposition angle as are therefore devoid of this third portion 105C (and for some zones, which had not been subjected to the ion beam emitted at the first deposition angle α₁ or emitted at the second deposition angle α₂, they are, at this stage, completely devoid of ferroelectric material).

The example represented in FIG. 3 involves the emission of ion beams at three distinct deposition angles. The present invention is of course not limited to three deposition angles. There may be only two or more than three. Moreover, generalising to a higher number of deposition angles makes it possible to obtain an almost continuous variation in the thickness of the layer of ferroelectric material in the cavity.

In practice, the change in orientation of the ion beam (i.e. the change in deposition angle) is implemented by positioning the support layer 10 on a manufacturing support (not represented) and by tilting this manufacturing support so as to obtain the desired deposition angle.

Furthermore, in order to obtain circular deposition symmetry for each part of the layer of ferroelectric material (and therefore for the layer of ferroelectric material itself), the manufacturing support can be rotated about an axis orthogonal to the bottom wall 52 of the cavity 50. This can be implemented irrespective of the deposition method considered in the present invention.

Alternatively, the change in orientation of the ion beam can be implemented by changing orientation of the target from which the atoms are extracted (and from which the ion beam is formed) so as to obtain the different deposition angles required.

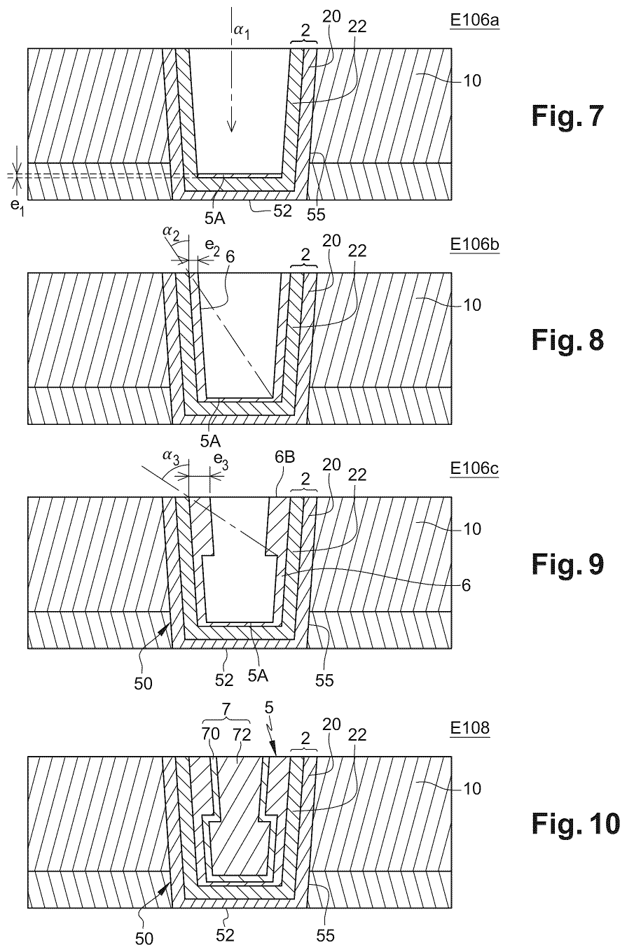

Based on this principle of anisotropic deposition, the method for manufacturing the ferroelectric storage device 1 then comprises, in step E106, a step E106a of depositing the first part 5A of the layer of ferroelectric material 5. This step is represented in FIG. 7.

As described previously, this first part 5A is deposited in the cavity 50 at a first deposition angle α₁. This step E106a is implemented so as to obtain a thickness e₁ of ferroelectric material, for the first part 5A, in the cavity 50.

Herein, the first part 5A is deposited at the bottom wall 52 of the cavity 50. This means that, in this first example of implementation of the manufacturing method according to an embodiment of the invention, the first deposition angle α₁ is substantially zero.

The step E106 of depositing the layer of ferroelectric material 5 then comprises a step E106b of depositing a second part 6 of the layer of ferroelectric material 5. This step E106b is represented in FIG. 8.

As described previously, this second part 6 is deposited in the cavity 50, at a second angle α₂. This step E106b is implemented so as to obtain a second part 6 with a thickness e₂ (in the cavity 50).

Herein, the second part 6 is deposited onto the side wall 55 of the cavity 50. The second deposition angle α₂ is therefore selected on the basis of the dimensions of the cavity 50 to allow deposition (by ion beam) only on the side wall 55 of the cavity 50.

Furthermore, in order to ensure circular symmetry of the deposition of this second part 6 of the layer of ferroelectric material 5, step E106b comprises, for example, rotating the manufacturing support (not represented) in order to ensure that the second part 6 is deposited onto the entire side wall 55 of the cavity 50. This can be implemented irrespective of the deposition method considered in the present invention.

Alternatively, this circular symmetry of the deposition can be achieved by changing orientation of the target from which the atoms are extracted (and from which the ion beam is formed).

Finally, as is visible in FIG. 4, the step E106 of depositing the layer of ferroelectric material 5 herein comprises a step E106c of depositing a third portion 6B of the layer of ferroelectric material 5. This step E106c is represented in FIG. 9.

This second part 6 is deposited in the cavity 50 at a third angle α₃. This step E106c is carried out so as to obtain a third part 6B with a thickness e₃ (in the cavity 50).

Herein, the third part 6B is deposited at the side wall 55 of the cavity 50 (and even here at the end of the side wall 55, opposite to the bottom wall 52 of the cavity 50). The third deposition angle α₃ is therefore herein selected to allow deposition (by ion beam) only on the zone concerned of the side wall 55 of the cavity 50.

Furthermore, in order to ensure, herein too, circular symmetry of the deposition of this third part 6B of the layer of ferroelectric material 5, step E106c comprises, for example, rotating the manufacturing support (not represented) in order to ensure that the third part 6B is deposited onto the zone concerned of the side wall 55 of the cavity 50. This can be implemented irrespective of the deposition method considered in the present invention.

Alternatively, this circular symmetry of deposition can be achieved by changing orientation of the target from which the atoms are extracted (and from which the ion beam is formed).

Finally, at the end of step E106, the layer of ferroelectric material 5 is formed in the cavity 50. In this first example of the method for manufacturing the ferroelectric material device 1, the layer of ferroelectric material 5 comprises the first part 5A having thickness e₁ formed on the bottom wall 52 of the cavity 50, the second part 6 having thickness e₂ formed on the side wall 55 of the cavity 50 and the third part 6B having thickness e₃ formed on part of the side wall 55 of the cavity 50.

The thicknesses e₁, e₂, e₃ are herein distinct. This implies that it will be necessary to apply different voltages for reading information stored in the intermediate polarisation state associated with each of the first part 5A, the second part 6 and the third part 6B.

It is to be noted herein that step E106c may be omitted if it is desired that the layer of ferroelectric material comprises only two different thicknesses. Of course, step E106 may comprise additional steps corresponding to the deposition of additional portions of the layer of ferroelectric material having other thicknesses (these depositions being implemented at other deposition angles, for example).

The method then continues, in step E108, with depositing the second layer 7. This step E108 is represented in FIG. 10.

The second layer 7 is formed on the layer of ferroelectric material 5 obtained at the end of step E106.

Depositing the second layer 7 is herein conformally made.

As previously indicated, the second layer 7 can herein comprise a first sub-layer 70 and a second sub-layer 72.

Step E108 of depositing the second layer 7 therefore comprises two sub-steps: a first sub-step E108a of depositing the first sub-layer 70 and a second sub-step 108b of depositing the second sub-layer 72.

The first sub-layer 70 is therefore first deposited, conformally, onto the layer of ferroelectric material 5 (step E108a). In practice, the first sub-layer 70 is formed, for example, by sputtering in a vacuum deposition chamber. In the case where the first sub-layer 70 is formed of titanium nitride, this is a reactive sputtering process.

Alternatively, the first sub-layer can be formed by chemical vapour deposition.

Then, the second sub-layer 72 of the second layer 7 is deposited, conformally, onto the first sub-layer 70 (step E108b). As is visible in FIG. 10, the second sub-layer 72 is formed so as to fill all the remaining space in the cavity 50. Therefore, it achieves a ferroelectric storage device 1 completely integrated into the cavity 50 and without any projection or recess formed relative to the surface of the support layer 10. The assembly formed by the support layer 10 into which the ferroelectric storage device 1 is integrated therefore has a uniform surface.

In practice, the second sub-layer 72 is formed, for example, by sputtering in a vacuum deposition chamber. In practice, the second sub-layer 72 of the second layer 7 is formed in the same deposition chamber as the first sub-layer 70 of the second layer 7.

In the case where the second sub-layer 72 is made of titanium nitride, this is a reactive sputtering process.

In practice, although this is not visible in the appended figures, it is not excluded that the different layers of the ferroelectric storage device 1 are also deposited onto the front face (free surface opposite to the bottom wall 52) of the support layer 10. Thus, optionally, in order to ensure flatness and uniformity of the ferroelectric storage device 1 (and in particular of the free surface of the device 1), there can be provided a planarisation step, after step E108. This planarisation step is implemented, for example, by Chemical Mechanical Polishing (CMP). Any other adapted method can be used (especially masking methods).

This planarisation step is particularly beneficial because, by virtue of making the surface of the device 1 uniform, it improves electrical performance of the ferroelectric storage device and ensures better quality interconnections.

Alternatively, an encapsulation step may be provided after this planarisation step. Finally, connection to the second layer 7 can be implemented.

Thus, at the end of the manufacturing method according to this first example, the ferroelectric storage device 1 obtained comprises a layer of ferroelectric material 5 having variable thickness. Herein, this variability in thickness is achieving by varying the difference in uniformity of the deposition between the bottom wall and the side wall of the cavity. More particularly, differences in thickness are achieved by selecting optimum conditions for the deposition of the ferroelectric material by judiciously controlling tilt of the atom flows used for this deposition.

As previously indicated, the variability in thicknesses makes it possible to introduce non-uniformities in the ferroelectric properties of the layer of ferroelectric material. This non-uniformity of properties especially makes it possible to increase differences between the voltage ranges to be applied to access the different intermediate polarisation states.

This avoids overlap between the voltage ranges concerned and therefore enables unambiguous identification of the intermediate polarisation states related to the information read.

In addition, the manufacturing method according to this first example makes it possible to obtain a three-dimensional architecture of the ferroelectric storage device 1. This makes it possible especially to increase the surface area of the capacity of the ferroelectric storage device 1.

According to one alternative implementation of this first example, the manufacturing method may comprise, between the step E106 of depositing the layer of ferroelectric material and the step E108 of depositing the second layer, a step of implanting a doping element in the layer of ferroelectric material formed in step E106. This step enables the layer of ferroelectric material to be doped with the doping element.

In practice, the implantation step is implemented, for example, in a reactor different from the deposition chamber for the first layer and the layer of ferroelectric material.

This is herein, for example, a step of ionically implanting silicon (which is the doping element) into the layer of ferroelectric material. Implantation doses are, for example, between 1.10¹⁴ cm⁻² and 1.10¹⁵ cm⁻². In an embodiment, the implantation dose is between 0.3.10¹⁵ cm⁻² and 1.10¹⁵ cm⁻².

FIG. 11 represents, in the form of a flow chart, a second example of the manufacturing method in accordance with the invention.

This second example of the manufacturing method is similar to the first example described previously. Therefore, only the differences relative to this first example are described in detail below.

As is visible in FIG. 11, the manufacturing method first comprises a step E200 (similar to step E100) of providing a support layer 10 on which the ferroelectric storage device 1 will be formed. In practice, this support layer 10 is provided with at least one logic component associated with a metal interconnection element (not represented) for connecting the ferroelectric storage device 1 to lower metal levels.

The manufacturing method then continues with step E202 (similar to step E102 described previously), during which the cavity 50 (in which the ferroelectric storage device 1 will be formed) is formed.

In practice, this step E202 is implemented by isotropic etching to form the bottom wall 52 and the side wall 55 of the cavity 50. It is, for example, dry chemical etching.

As previously described, the side wall 55 of the cavity 50 is made in such a way as to form the tilt angle β relative to the axis z parallel to a direction normal to the bottom wall 52.

As is visible in FIG. 11, the manufacturing method according to this second example continues with step E204, by depositing the first layer 2. Step E204 is similar to step E104 described for the first example.

This first layer 2 is deposited in the cavity 50. More particularly, the first layer 2 is deposited along the bottom wall 52 and the side wall 55 of the cavity 50. The first layer 2 therefore lines and embraces the shape of the cavity 50.

As previously indicated, the first layer 2 herein comprises a first sub-layer 20 and a second sub-layer 22.

Step E204 of depositing the first layer 2 therefore comprises two sub-steps: a first sub-step E204a of depositing the first sub-layer 20 and a second sub-step E204b of depositing the second sub-layer 22.

The first sub-layer 20 is therefore first deposited, conformally, in the cavity 50 (step E204a). In practice, the first sub-layer 20 is formed, for example, by an atomic layer deposition (or ALD) method or by chemical vapour deposition.

Alternatively, the first sub-layer 20 can be formed by sputtering in a vacuum deposition chamber. In the case where the first sub-layer 20 is formed of titanium nitride, this is a reactive sputtering process.

The second sub-layer 22 of the first layer 2 is then conformally deposited onto the first sub-layer 20 (step E204b). The second sub-layer 22 is formed by sputtering in a vacuum deposition chamber, for example. In practice, the second sub-layer 22 of the first layer 2 is formed in the same deposition chamber as the first sub-layer 20 of the first layer 2.

In the case where the second sub-layer 22 is made of titanium nitride, this is a reactive sputtering process.

The method then continues with step E206 of depositing the layer of ferroelectric material 5 onto the first layer 2. More particularly, the layer of ferroelectric material 5 is deposited onto the second sub-layer 22 of the first layer 2.

Depositing the layer of ferroelectric material 5 is also herein anisotropically implemented. On the other hand, the deposition of the layer of ferroelectric material 5 is herein non-conformal.

In practice, the layer of ferroelectric material 5 is deposited by a physical vapour deposition (PVD) method.

In an embodiment herein, the layer of ferroelectric material 5 is deposited by an lon Beam Deposition (IBD) method. Alternatively, the layer of ferroelectric material can be deposited by a vacuum evaporation deposition method. Similar deposition rates can be achieved using a vacuum evaporation deposition method and an ion beam deposition method. In practice, in the case a vacuum evaporation deposition method, a crucible comprises the material to be deposited. This crucible is heated by the Joule effect. By varying the current intensity, it is then possible to vary the deposition rate.

The anisotropic nature of the deposition is also herein based on controlling orientation of a target, from which atoms are extracted, relative to a substrate (herein, for example, the support layer). Atoms extracted from the target then form an ion beam associated with a corresponding direction of deposition. Thus, the anisotropic nature of the deposition is associated with different directions of deposition (using the deposition methods introduced previously).

Based on this principle of anisotropic deposition, the method for manufacturing the ferroelectric storage device 1 then comprises, in step E206, a step E206a (similar to step E106a described previously) of depositing the first part 5A of the layer of ferroelectric material 5.

As described previously, this first part 5A is deposited in the cavity 50 at a first deposition angle α₁. This step E206a is carried out so as to obtain a thickness e₁ of ferroelectric material, for the first part 5A, in the cavity 50.

Herein, the first part 5A is deposited at the bottom wall 52 of the cavity 50. This means that, in this second example of implementation of the manufacturing method according to the invention, the first deposition angle α₁ is substantially zero.

The step E206 of depositing the layer of ferroelectric material 5 then comprises a step E206b of depositing a second part 6A of the layer of ferroelectric material 5. This step E206B is represented in FIG. 12.

As described previously, this second part 6A is deposited in the cavity 50, at a second angle α₂. This step E206b is implemented so as to obtain a second part 6A with a thickness e₂ (in the cavity 50).

Herein, the second part 6A is deposited at the side wall 55 of the cavity 50 and at a part of the bottom wall 52 of the cavity 50. The second deposition angle α₂ is therefore herein selected to allow deposition (by ion beam) at the side wall 55 and at a part of the bottom wall of the cavity 50.

Furthermore, in order to ensure circular symmetry of the deposition of this second part 6A of the layer of ferroelectric material 5, step E206b comprises, for example, rotating the manufacturing support (not represented) in order to ensure that the second part 6A is deposited onto the whole of the side wall 55 and on the part concerned of the bottom wall 52 of the cavity 50. This can be implemented irrespective of the deposition method considered in the present invention.

Alternatively, this circular symmetry of the deposition can be achieved by changing orientation of the target from which the atoms are extracted (and from which the ion beam is formed).

Finally, as is visible in FIG. 11, step E206 of depositing the layer of ferroelectric material 5 herein comprises a step E206c (similar to step E106c described previously) of depositing a third portion 6C of the layer of ferroelectric material 5. This step E206c is represented in FIG. 13.

This third part 6C is deposited in the cavity 50 at a third angle α₃. This step E206c is implemented so as to obtain a third part 6C with a thickness e₃ (in the cavity 50).

Herein, the third part 6C is deposited at the side wall 55 of the cavity 50 (and even here at the end of the side wall 55, opposite to the bottom wall 52 of the cavity 50). The third deposition angle α₃ is therefore selected here to allow deposition (by ion beam) only on the zone concerned of the side wall 55 of the cavity 50.

Furthermore, in order to ensure, herein too, circular symmetry of the deposition of this third part 6C of the layer of ferroelectric material 5, step E206c comprises, for example, rotating the manufacturing support (not represented) in order to ensure that the third part 6C is deposited onto the zone concerned of the side wall 55 of the cavity 50. This can be implemented irrespective of the deposition method considered in the present invention.

Alternatively, this circular symmetry of the deposition can be achieved by changing orientation of the target from which the atoms are extracted (and from which the ion beam is formed).

Finally, at the end of step E206, the layer of ferroelectric material 5 is formed in the cavity 50. In the second example of the method for manufacturing the ferroelectric material device 1, the layer of ferroelectric material 5 comprises the first part 5A having thickness e₁ formed on the bottom wall 52 of the cavity 50, the second part 6A having thickness e₂ formed on the side wall 55 and on part of the bottom wall of the cavity 50 and the third part 6C having thickness e₃ formed on part of the side wall 55 of the cavity 50.

The thicknesses e₁, e₂, e₃ are herein distinct. This means that it will be necessary to apply different voltages for reading information stored in the intermediate polarisation state associated with each of the first part 5A, the second part 6A and the third part 6C.

It is herein to be noted that step E206c may be omitted if it is desired that the layer of ferroelectric material comprises only two different thicknesses. Of course, step E206 (as for step E106 described previously) may comprise additional steps corresponding to the deposition of additional portions of the layer of ferroelectric material at other thicknesses (these depositions being implemented at other deposition angles).

The method then continues, in step E208, with depositing the second layer 7. This step E208 is represented in FIG. 14. This step is similar to step E108 described previously for the first example.

The second layer 7 is formed on the layer of ferroelectric material 5 obtained at the end of step E206.

Depositing the second layer 7 is conformally performed.

As previously indicated, the second layer 7 can herein comprise a first sub-layer 70 and a second sub-layer 72.

Step E208 of depositing the second layer 7 therefore comprises two sub-steps: a first sub-step E208a of depositing the first sub-layer 70 and a second sub-step E208b of depositing the second sub-layer 72.

The first sub-layer 70 is therefore first deposited, conformally, onto the layer of ferroelectric material 5 (step E208a). In practice, the first sub-layer 70 is formed by sputtering in a vacuum deposition chamber, for example. In the case where the first sub-layer 70 is formed of titanium nitride, this is a reactive sputtering process.

Alternatively, the first sub-layer can be formed by chemical vapour deposition.

Then, the second sub-layer 72 of the second layer 7 is conformally deposited onto the first sub-layer 70 (step E208b). As is visible in FIG. 14, the second sub-layer 72 is formed so as to fill all the remaining space in the cavity 50. This then makes it possible to obtain a ferroelectric storage device 1 completely integrated into the cavity 50 and without any projection or recess formed relative to the surface of the support layer 10. The assembly formed by the support layer 10 into which the ferroelectric storage device 1 is integrated therefore has a uniform surface.

In practice, the second sub-layer 72 is formed by sputtering in a vacuum deposition chamber, for example. In practice, the second sub-layer 72 of the second layer 7 is formed in the same deposition chamber as the first sub-layer 70 of the second layer 7.

In the case where the second sub-layer 72 is made of titanium nitride, this is a reactive sputtering process.

In practice, although this is not visible in the appended figures, it is not excluded that the different layers of the ferroelectric storage device 1 are also deposited onto the front face (free surface opposite to the bottom wall 52) of the support layer 10. Thus, optionally, in order to ensure flatness and uniformity of the ferroelectric storage device 1 (and in particular the free surface of the device 1), a planarisation step may also be provided, after step E208. This planarisation step is carried out, for example, by chemical mechanical polishing (CMP). Any other adapted method can be used (especially masking methods).

This planarisation step is particularly beneficial because, by virtue of making the surface of the device 1 uniform, it improves electrical performance of the ferroelectric storage device and ensures better quality interconnections.

Alternatively, an encapsulation step may be provided after this planarisation step. Finally, connection to the second layer 7 can be implemented.

Thus, at the end of the manufacturing method according to this second example, the ferroelectric storage device 1 obtained comprises a layer of ferroelectric material having variable thickness. Herein, this variability in thickness is achieved by varying the difference in uniformity of the deposition between the bottom wall and the side wall of the cavity. More particularly, the differences in thickness are achieved by selecting optimum conditions for depositing the ferroelectric material by judiciously controlling the inclination of the atom flows used for this deposition.

As indicated previously, this variability in thickness introduces non-uniformity in the ferroelectric properties of the layer of ferroelectric material. This non-uniformity of properties especially makes it possible to increase the differences between the voltage ranges to be applied to access the different intermediate polarisation states. This makes it possible to avoid overlap between the voltage ranges concerned and therefore to unambiguously identify the intermediate polarisation states concerned by the information read.

In addition, the manufacturing method according to this second example also makes it possible to obtain a three-dimensional architecture of the ferroelectric storage device 1. This makes it possible, especially, to increase the surface area of the capacity of the ferroelectric storage device 1.

According to one alternative implementation of this second example, the method for manufacturing may comprise, between the step E206 of depositing the layer of ferroelectric material and the step E208 of depositing the second layer, a step of implanting a doping element into the layer of ferroelectric material formed in step E206. This step enables the layer of ferroelectric material to be doped with the doping element.

In practice, the implantation step is carried out, for example, in a reactor different from the chamber for depositing the first layer and the layer of ferroelectric material.

Herein, for example, it is a step of ionically implanting silicon (which is the doping element) into the layer of ferroelectric material. The implantation doses are, for example, between 1.10¹⁴ cm⁻² and 1.10¹⁵ cm⁻². In an embodiment, the implantation dose is between 0.3.10¹⁵ cm⁻² and 1.10¹⁵ cm⁻².

### Applications

The ferroelectric storage device according to an embodiment of the invention finds a favoured application within the scope of FeRAM-type resistive memories.

It also finds a particular application within the scope of transistors, for example of the FeMFET («Ferroelectric-metal field effect transistor») type.

The ferroelectric storage device according to an embodiment of the invention can also be used within the scope of ferroelectric tunnel junctions (FTJs). In this case, an additional layer is added between the layer of ferroelectric material and the second layer. This additional layer comprises a dielectric material. This dielectric material is for example an aluminium oxide Al₂O₃.

In the case of some of the applications mentioned (e.g. FeRAM or FTJ type memories), the first layer forms a first electrode (e.g. a lower electrode), the second layer forms a second electrode (e.g. an upper electrode) and the layer of ferroelectric material forms a memory layer.

Expressions such as “comprise”, “include”, “incorporate”, “contain”, “is” and “have” are to be construed in a non-exclusive manner when interpreting the description and its associated claims, namely construed to allow for other items or components which are not explicitly defined also to be present. Reference to the singular is also to be construed in be a reference to the plural and vice versa.

The articles “a” and “an” may be employed in connection with various elements and components of compositions, processes or structures described herein. This is merely for convenience and to give a general sense of the compositions, processes or structures. Such a description includes “one or at least one” of the elements or components. Moreover, as used herein, the singular articles also include a description of a plurality of elements or components, unless it is apparent from a specific context that the plural is excluded.

As used herein in the specification and in the claims, the phrase “at least one”, in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified.

A person skilled in the art will readily appreciate that various features, elements, parameters disclosed in the description may be modified and that various embodiments disclosed may be combined without departing from the scope of the invention. For example, various aspects of the present disclosure may be used alone, in combination, or in a variety of arrangements not specifically described in the embodiments described in the foregoing and is therefore not limited in its application to the details and arrangement of components set forth in the foregoing description or illustrated in the drawings. For example, aspects described in one embodiment may be combined in any manner with aspects described in other embodiments.

Having described above several aspects of at least one embodiment, it is to be appreciated various alterations, modifications, and improvements will readily occur to those skilled in the art. Such alterations, modifications, and improvements are intended to be aspects of this disclosure. Accordingly, the foregoing description and drawings are by way of example only.

1. A method for manufacturing a ferroelectric storage device comprising:
providing a support layer;
forming a cavity in the support layer, the cavity comprising a bottom wall and a side wall, the side wall forming a tilt angle relative to a direction normal to the bottom wall;
depositing a first layer in the cavity;
depositing, by a physical vapour deposition method, a layer of ferroelectric material into the cavity, the layer of ferroelectric material comprising a first part having a first thickness and a second part having a second thickness, the first thickness and the second thickness being distinct,
depositing the layer of ferroelectric material comprising
a) depositing the first part of the layer of ferroelectric material along a first direction associated with a first deposition angle formed relative to a direction normal to the bottom wall,
b) depositing the second part of the layer of ferroelectric material along a second direction associated with a second deposition angle formed relative to the direction normal to the bottom wall, the second deposition angle and the first deposition angle being different, and then
depositing a second layer into the cavity, the layer of ferroelectric material extending between the first layer and the second layer.

2. The manufacturing method according to claim 1, wherein depositing the layer of ferroelectric material is anisotropically implemented.

3. The manufacturing method according to claim 1, wherein depositing the layer of ferroelectric material is non-conformally implemented.

4. The manufacturing method according to claim 1, wherein depositing the layer of ferroelectric material is implemented by an ion beam deposition method or by an evaporation deposition method.

5. The manufacturing method according to claim 1, wherein the first deposition angle and the second deposition angle are less than 90 degrees.

6. The manufacturing method according to claim 1, wherein depositing the first part of the layer of ferroelectric material is implemented by orienting a first unidirectional ion beam along the first direction and depositing the second part of the layer of ferroelectric material is implemented by orienting a second unidirectional ion beam along the second direction.

7. The manufacturing method according to claim 6, wherein a change in the orientation of the first unidirectional ion beam and/or the second unidirectional ion beam is performed by tilting the support layer.

8. The manufacturing method according to claim 6, wherein a change in the orientation of the first unidirectional ion beam and/or the second unidirectional ion beam is performed by tilting a target from which the first unidirectional ion beam and/or the second unidirectional ion beam are formed.

9. The manufacturing method according to claim 1, wherein the layer of ferroelectric material comprises hafnium dioxide or hafnium dioxide doped with a doping element or an alloy HfₓZr₁₋ₓO₂, with 0<x<1.

10. The manufacturing method according to claim 1, comprising, before depositing the second layer, implanting a doping element into the layer of ferroelectric material so as to dope the layer of ferroelectric material with the doping element.
